(19) United States
(12) Patent Application Publication
(10) Pub. No.: US 2022/0152780 A1
(43) Pub. Date: May 19, 2022

(54) SUBSTRATE PROCESSING APPARATUS AND SUBSTRATE PROCESSING METHOD

(71) Applicant: Tokyo Electron Limited, Tokyo (JP)

(72) Inventors: Yuichi DOUKI, Kumamoto (JP); Kouzou KANAGAWA, Kumamoto (JP); Junichi KITANO, Kumamoto (JP)

(21) Appl. No.: 17/522,191

(22) Filed: Nov. 9, 2021

(30) Foreign Application Priority Data
Nov. 19, 2020 (JP) 2020-192369

(51) Int. Cl. B24B 49/16; B24B 57/02; B24B 37/015; B24B 37/27

(52) U.S. Cl. CPC B24B 49/16; B24B 37/27; B24B 37/015; B24B 57/02

(57) ABSTRACT

A substrate processing apparatus includes: a cassette block configured to mount a cassette that accommodates a substrate; a processing block configured to process the substrate; a relay block configured to relay the substrate between the cassette block and the processing block; and a controller. The processing block includes a processing module that performs a removal process of removing a part of the substrate. The relay block includes a weight measuring unit that measures a weight of the substrate before or after being processed by the processing block. The controller includes a removal amount determination unit that calculates a weight difference of the substrate before and after being processed by the processing block using the measurement result of the weight measuring unit and determines whether a removal amount by the removal process is within a permissible range.

### CROSS-REFERENCE TO RELATED APPLICATION

This application is based on and claims priority from Japanese Patent Application No. 2020-192369 filed on Nov. 19, 2020 with the Japan Patent Office, the disclosure of which is incorporated herein in its entirety by reference.

### TECHNICAL FIELD

The present disclosure relates to a substrate processing apparatus and a substrate processing method.

### BACKGROUND

The film forming processing apparatus described in Japanese Patent Laid-Open Publication No. 2003-332239 includes a measuring unit that automatically measures the weight of a semiconductor wafer before a film forming processing on the way of transferring the wafer from a wafer cassette to a film forming processing chamber, and a measuring unit that automatically measures the weight of the semiconductor wafer after the film forming processing. Further, the film forming processing apparatus includes a database that stores the weight of the semiconductor wafer measured before and after the film forming processing, and a calculation unit that calculates a film thickness from the weight. Also, the film forming processing apparatus further includes a control unit that controls the film forming conditions from the film thickness.

The plating apparatus described in Japanese Patent Laid-Open Publication No. 2018-188708 includes a measuring unit that measures the weight of an object to be plated before the plating processing and the weight of the object to be plated after the plating processing. Further, the plating apparatus includes a determination unit that determines whether the weight of the plating portion is within a predetermined range by regarding a difference between the weight before the processing and the weight after the processing as the weight of the plating portion. The plating apparatus changes the conditions of the plating processing when the weight of the plated portion deviates from a predetermined range.

In the etching end point detection method described in Japanese Patent Laid-Open Publication No. H01-236633, a wafer is pulled up from an etching solution and the weight of the wafer is measured. Then, it is detected that the decrease in weight has reached a constant value, and the end point of etching is detected. The wafer is submerged in the etching solution for a predetermined time and the weight of the wafer is measured repeatedly until the decrease in weight becomes a constant value.

The method for controlling a semiconductor device manufacturing process described in Japanese Patent No. 5957023 includes a step of measuring a mass change of a semiconductor wafer in each manufacturing process.

### SUMMARY

According to an aspect of the present disclosure, a substrate processing apparatus includes: a cassette block configured to mount a cassette that accommodates a substrate; a processing block configured to process the substrate; a relay block configured to relay the substrate between the cassette block and the processing block; and a controller. The cassette block includes a mounting stage on which the cassette is mounted, and a first transfer unit that transfers the substrate between the mounting stage and the relay block. The processing block includes a processing module that performs a removal process of removing a part of the substrate, and a second transfer unit that transfers the substrate between the processing module and the relay block. The relay block includes a weight measuring unit that measures a weight of the substrate before or after being processed by the processing block. The controller includes a removal amount determination unit that calculates a weight difference of the substrate before and after being processed by the processing block using the measurement result of the weight measuring unit and determines whether a removal amount by the removal process is within a permissible range.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a substrate processing apparatus according to a first embodiment.

FIG. 2 is a view illustrating an example of components of a control device in a functional block.

FIG. 3 is a perspective view illustrating an example of a cassette block and a relay block.

FIG. 4 is a cross-sectional view illustrating an example of an alignment unit.

FIG. 5 is a cross-sectional view illustrating an example of weight measurement in the alignment unit.

FIG. 6 is a plan view illustrating an example of a lot forming unit.

FIG. 7 is a side view illustrating an example of the operation of the lot forming unit.

FIG. 8 is a side view illustrating an example of the operation of the lot forming unit, following FIG. 7.

FIG. 9 is a side view illustrating an example of the operation of the lot forming unit, following FIG. 8.

FIG. 10 is a cross-sectional view illustrating an example of a batch type processing module.

FIG. 11 is another cross-sectional view of the processing module of FIG. 10.

FIG. 12 is a cross-sectional view illustrating an example of liquid processing in a drying module.

FIG. 13 is a cross-sectional view illustrating an example of drying in the drying module.

FIG. 14 is a cross-sectional view illustrating an example of weight measurement in the drying module.

FIG. 15 is a plan view illustrating a substrate processing apparatus according to a second embodiment.

FIG. 16 is a front view illustrating the substrate processing apparatus according to the second embodiment.

FIG. 17 is a plan view illustrating an example of a transition unit.

FIG. 18 is a cross-sectional view taken along line XVIII-XVIII of FIG. 17.

FIG. 19 is a cross-sectional view illustrating a part of FIG. 19.

FIG. 20 is a cross-sectional view illustrating an example of a single-wafer processing module.

FIG. 21 is a cross-sectional view illustrating an example of weight measurement in the single-wafer processing module.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In each drawing, the same or corresponding components may be designated by the same reference numerals and descriptions thereof may be omitted. The X-axis direction, the Y-axis direction, and the Z-axis direction are perpendicular to each other. The X-axis direction and the Y-axis direction are the horizontal directions, and the Z-axis direction is the vertical direction.

### First Embodiment

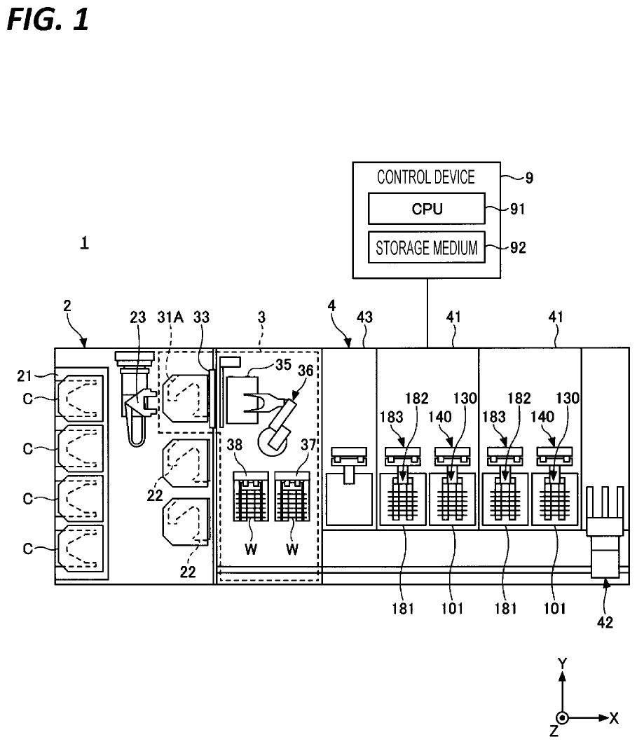

The substrate processing apparatus 1 illustrated in FIG. 1 is a batch type. The substrate processing apparatus 1 includes a cassette block 2, a relay block 3, a processing block 4, and a control device 9. The cassette block 2 mounts a cassette C. The cassette C accommodates a substrate W. The substrate W includes a base substrate such as a semiconductor substrate or a glass substrate, and a film formed on the base substrate. The processing block 4 performs a removal process for removing a part of the substrate W, such as etching or dissolving a metal film or a resin film coated on the surface of the substrate W with a processing liquid. The relay block 3 relays the substrate W between the cassette block 2 and the processing block 4. The cassette block 2, the relay block 3, and the processing block 4 are arranged in this order in the positive direction of the X-axis.

The cassette block 2 has a mounting unit 21 on which the cassette C is mounted. The cassette C accommodates a plurality of (e.g., 25) substrates W, and is loaded into and unloaded from the cassette block 2. The cassette C horizontally holds each of the plurality of substrates W arranged at a first pitch in the vertical direction.

The cassette block 2 has a storage unit 22 for storing the cassette C. The storage unit 22 stores the cassette C being transferred between the mounting unit 21 and loading/unloading units 31A and 31B of the relay block 3. The storage unit 22 may store the cassette C accommodating the substrate W, or may store an empty cassette C.

The cassette block 2 has a first transfer unit 23 that transfers the substrate W between the mounting unit 21 and the loading/unloading units 31A and 31B of the relay block 3. The first transfer unit 23 is, for example, an articulated robot. By transferring the cassette C, the first transfer unit 23 transfers a plurality of (e.g., 25) substrates W in a batch. The first transfer unit 23 may transfer an empty cassette C.

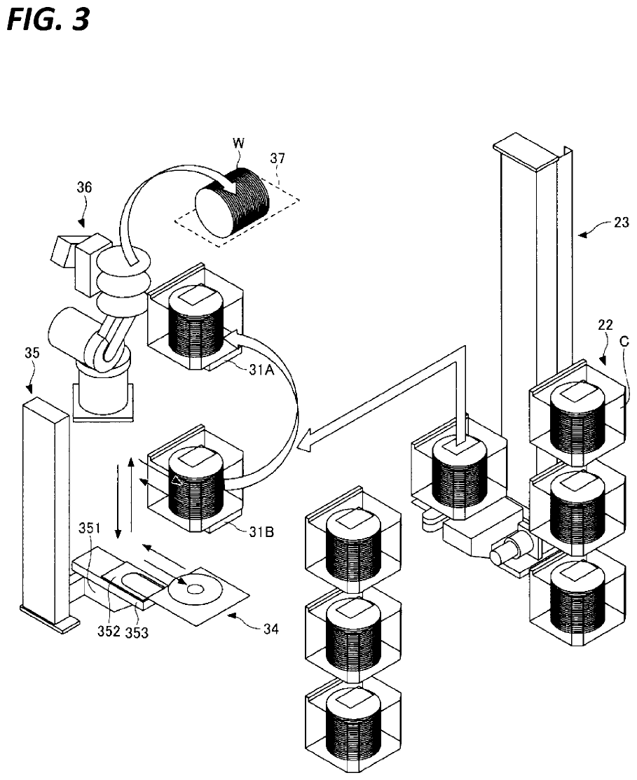

The relay block 3 relays the substrate W between the cassette block 2 and the processing block 4. The relay block 3 has loading/unloading units 31A and 31B on which the cassette C is mounted when the substrate W is loaded into and unloaded from the cassette C. The loading/unloading units 31A and 31B are arranged in the vertical direction as illustrated in FIG. 3. For example, the loading/unloading unit 31A is arranged in the upper stage, and the loading/unloading unit 31B is arranged in the lower stage.

The relay block 3 has an opening/closing mechanism 33 (see, e.g., FIG. 1) that opens/closes the door of the cassette C mounted on the loading/unloading units 31A and 31B. The substrate W is loaded into and unloaded from the cassette C with the opening of the cassette C opened. Further, the cassette C is transferred with the opening of the cassette C closed.

As illustrated in FIG. 3, the relay block 3 has an alignment unit 34 that adjusts the position of a notch of the substrate W. For example, the alignment unit 34 is arranged below the loading/unloading unit 31B in the lower stage. The alignment unit 34 adjusts the position of the notch of the substrate W before being processed by the processing block 4, but may adjust the position of the notch of the substrate W after being processed by the processing block 4.

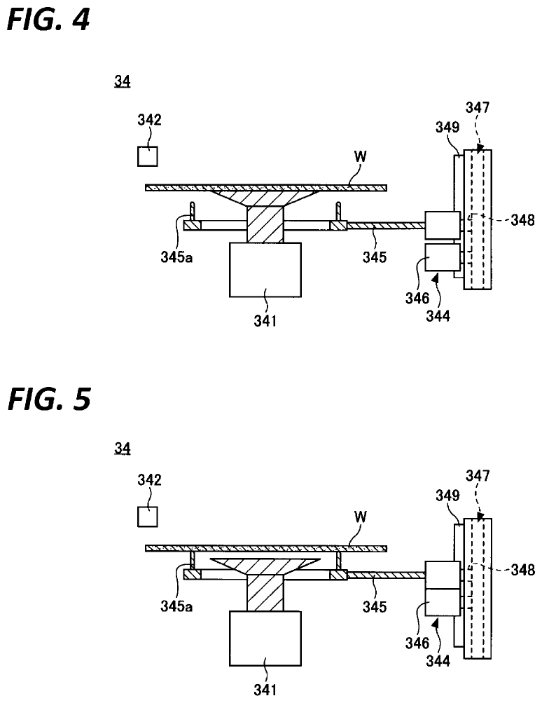

As illustrated in FIG. 4, the alignment unit 34 includes, for example, a spin chuck 341 that holds and rotates the substrate W horizontally, and a sensor 342 that detects the position of the notch of the substrate W. While the spin chuck 341 holds and rotates the substrate W, the sensor 342 detects the position of the notch of the substrate W, so that a rotation angle of the substrate W is adjusted and the position of the notch is adjusted.

An orientation flat instead of the notch may be formed on the substrate W. In such a case, the alignment unit 34 adjusts the position of the orientation flat.

The alignment unit 34 may include, for example, a weight measuring unit 344 that measures the weight of the substrate W, as illustrated in FIG. 5. The alignment unit 34 adjusts the position of the notch of the substrates W one by one and measures the weight of the substrate W.

The weight measuring unit 344 has an arm 345 that supports the substrate W from below. The arm 345 includes, for example, a plurality of (e.g., 3) pins 345a. The plurality of pins 345a are arranged on the outer side in the radial direction of the spin chuck 341, and lift the substrate W from the spin chuck 341.

Further, the weight measuring unit 344 has a weight sensor 346 on which the arm 345 is mounted. The weight sensor 346 measures a difference between the total weight of the arm 345 and the substrate W held by the arm 345, and the weight of the arm 345 to measure the weight of the substrate W. The weight sensor 346 transmits the measured data to the control device 9.

The weight measuring unit 344 has an elevating mechanism 347 that raises and lowers the arm 345 and the weight sensor 346. Further, the weight measuring unit 344 has a lock mechanism 348 that switches between a state in which the elevating mechanism 347 and the arm 345 are connected and a state in which the elevating mechanism 347 and the arm 345 are disconnected.

When the elevating mechanism 347 raises and lowers the arm 345, the lock mechanism 348 connects the elevating mechanism 347 and the arm 345. The driving force of the elevating mechanism 347 is transmitted to the arm 345, and the arm 345 is moved up and down. The weight sensor 346 measures the weight of the substrate W at a state where the arm 345 lifts the substrate W from the spin chuck 341.

When the weight sensor 346 measures the weight of the substrate W, the lock mechanism 348 disconnects the elevating mechanism 347 and the arm 345. As a result, the arm 345 may fall along a guide 349, and a load proportional to the weight of the arm 345 acts on the weight sensor 346. Therefore, the weight sensor 346 may measure the weight of the substrate W.

As illustrated in FIG. 3, the relay block 3 includes a single-wafer transfer unit 35 that transfers the substrates W one by one. The single-wafer transfer unit 35 unloads the substrate W from the cassette C mounted on the loading/unloading unit 31B in the lower stage and transfers the substrate W to the alignment unit 34. Further, the single-wafer transfer unit 35 receives the substrate W from the alignment unit 34, and loads the substrate W into the cassette C mounted on the loading/unloading unit 31B in the lower stage.

The single-wafer transfer unit 35 has a moving body 351 that may move in the vertical direction, and two transfer arms 352 and 353 that move back and forth independently of the moving body 351. By the two transfer arms 352 and 353, the unloading of the substrate W from the alignment unit 34 and the loading of the substrate W into the alignment unit 34 may be continuously performed, and the operating rate of the alignment unit 34 may be improved.

The cassette C accommodates the substrate W whose notch position is adjusted by the alignment unit 34. Thereafter, the cassette C is moved from the loading/unloading unit 31B in the lower stage to the loading/unloading unit 31B in the upper stage by the first transfer unit 23.

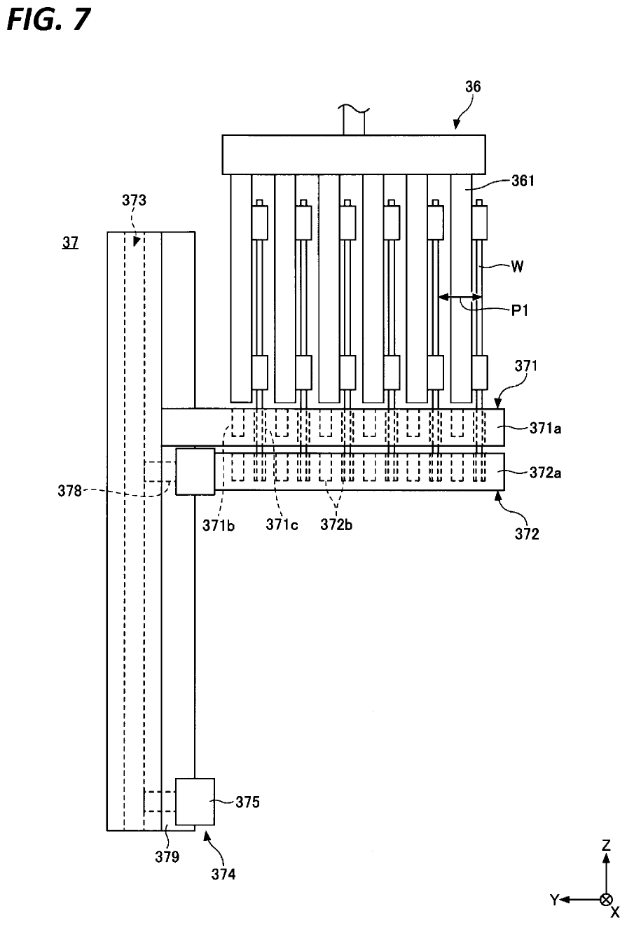

The relay block 3 includes a batch transfer unit 36 that simultaneously transfers a plurality of substrates W. The batch transfer unit 36 is, for example, an articulated robot, and has a transfer arm 361 at its tip as illustrated in FIG. 7. Like the cassette C, the transfer arm 361 holds a plurality of (e.g., 25) substrates W at the first pitch.

As illustrated in FIG. 3, the batch transfer unit 36 unloads a plurality of (e.g., 25) substrates W from the cassette C mounted on the loading/unloading unit 31A in the upper stage, and transfers the substrates W to a lot forming unit 37 (to be described later). On the way, the batch transfer unit 36 changes the arrangement direction of the substrate W from the Z-axis direction to the Y-axis direction.

Further, the batch transfer unit 36 receives a plurality of (e.g., 25) substrates W from a lot releasing unit 38 (to be described later), and carries the substrates W into an empty cassette C mounted on the loading/unloading unit 31A in the upper stage. On the way, the batch transfer unit 36 changes the arrangement direction of the substrate W from the Y-axis direction to the Z-axis direction.

As illustrated in FIG. 1, the relay block 3 includes a lot forming unit 37 that forms a lot including a plurality of (e.g., 50) substrates W. The lot forming unit 37 forms a lot by combining a plurality of (e.g., 25) substrates W arranged at the first pitch and a plurality of (e.g., 25) substrates W arranged at the same first pitch. The lot includes a plurality of (e.g., 50) substrates W arranged at a second pitch different from the first pitch.

The second pitch has, for example, a half value of the first pitch. One lot includes the substrate W accommodated in two cassettes C. By narrowing the pitch of the substrate W, the number of substrates W to be processed in a batch may be increased. The second pitch may be 1/n times the first pitch (n is a natural number of 2 or more), and one lot may include the substrates W accommodated in n cassettes C. The substrate W is processed by the processing block 4 for each lot.

The relay block 3 includes a lot releasing unit 38 that releases the lot. The lot releasing unit 38 disassembles a plurality of (e.g., 50) substrates W arranged at the second pitch into a plurality of (e.g., 25) substrates W arranged at the first pitch, and a plurality of (e.g., 25) substrates W arranged at the same first pitch. The lot is released after the lot has been processed in the processing block 4.

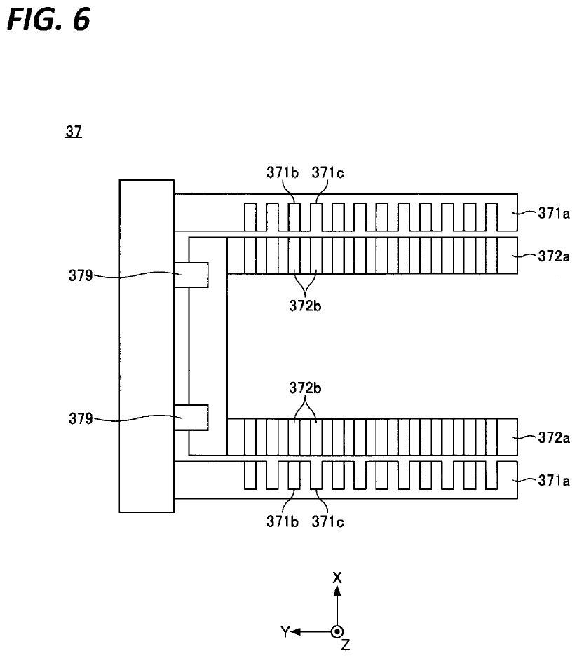

Next, the operation of the lot forming unit 37 will be described with reference to FIGS. 6 to 9. In FIGS. 6 to 9, the number of substrates W is illustrated to be smaller than the actual number due to space limitations in the drawings. The lot forming unit 37 includes a fixed hand 371, a movable hand 372, and an elevating mechanism 373. The fixed hand 371 and the movable hand 372 hold each of a plurality of substrates W arranged at intervals in the Y-axis direction vertically upright. The elevating mechanism 373 raises and lowers the movable hand 372 with respect to the fixed hand 371.

The fixed hand 371 has a plurality of arms 371a parallel to each other. The number of arms 371a is not limited to the one illustrated in the figure. Each arm 371a alternately includes a holding groove 371b that holds the substrate W and a passing groove 371c through which the substrate W passes. The pitch of the holding groove 371b is the first pitch, and the pitch of the passing groove 371c is also the first pitch.

The movable hand 372 also has a plurality of arms 372a parallel to each other. The number of arms 372a is not limited to the one illustrated in the figure. Each arm 372a includes a holding groove 372b that holds the substrate W. The pitch of the holding groove 372b is the second pitch. The second pitch is 1/n times the first pitch.

The elevating mechanism 373 raises and lowers the movable hand 372 between a position above the fixed hand 371 and a position below the fixed hand 371. First, as illustrated in FIG. 7, the movable hand 372 stops at a position below the fixed hand 371. Thereafter, the batch transfer unit 36 inserts a plurality of (e.g., 25) substrates W arranged at the first pitch P1 into the passing groove 371c of the fixed hand 371 and passes the substrates W to the movable hand 372. The movable hand 372 holds each of the plurality of substrates W arranged at the first pitch P1 vertically upright.

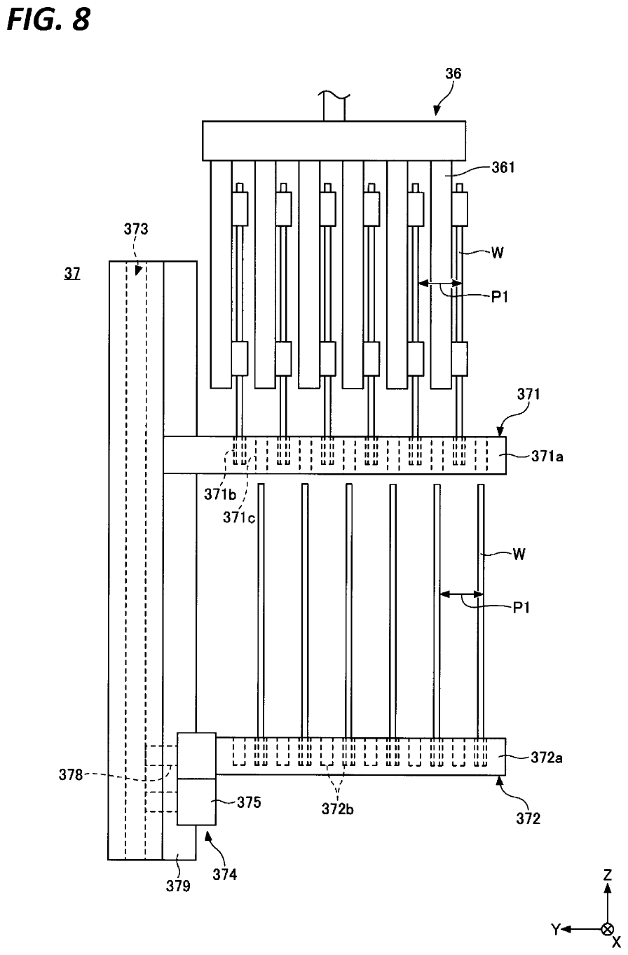

Next, as illustrated in FIG. 8, the elevating mechanism 373 lowers the movable hand 372 and retracts the plurality of substrates W held by the movable hand 372 below the fixed hand 371. Thereafter, the batch transfer unit 36 inserts a plurality of (e.g., 25) substrates W arranged at the first pitch P1 into the passing groove 372b of the fixed hand 371 and passes the substrates W to the fixed hand 371. The fixed hand 371 holds each of the plurality of substrates W arranged at the first pitch P1 vertically upright.

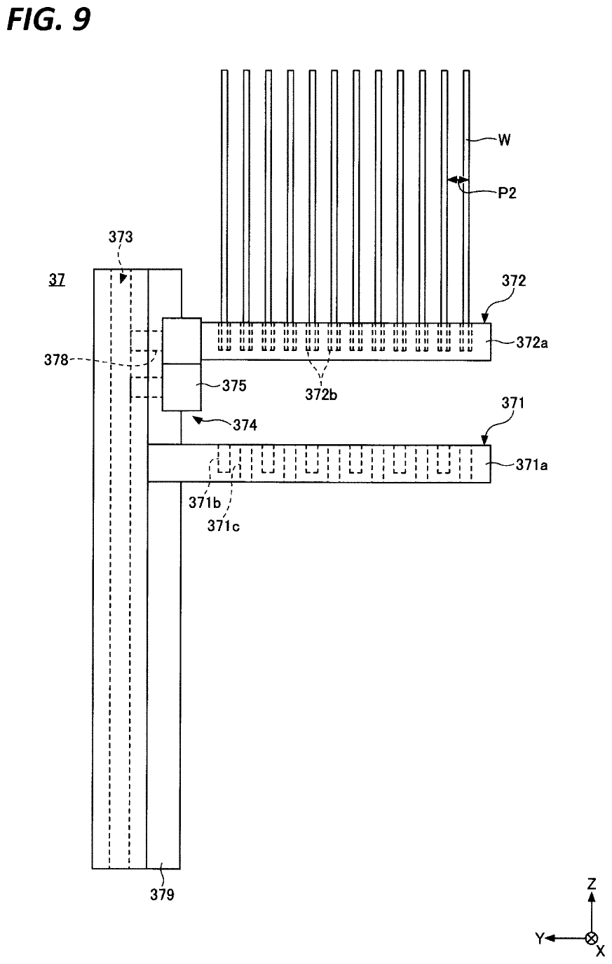

Next, as illustrated in FIG. 9, the elevating mechanism 373 raises the movable hand 372 to a position above the fixed hand 371. On the way, the movable hand 372 receives a plurality of substrates W held by the fixed hand 371 from the fixed hand 371, and the received substrate W and the originally held substrate W are combined to form a lot. The lot includes a plurality of substrates W arranged side by side at the second pitch P2.

The lot forming unit 37 may include a weight measuring unit 374 that measures the weight of the substrate W. The weight measuring unit 374 includes, for example, a weight sensor 375 on which the movable hand 372 is mounted. The weight sensor 375 measures a difference between the total weight of the movable hand 372 and the substrate W held by the movable hand 372, and the weight of the movable hand 372 to measure the weight of the substrate W.

The weight sensor 375 may measure the weight of the substrate W in lot units, or may measure the weight of the substrate W in cassette units. The weight sensor 375 may measure the weight of the substrate W of one lot and the weight of the substrate W of one cassette C, and estimate the difference as the weight of the substrate W of the remaining cassette C. The weight sensor 375 transmits the measured data to the control device 9

The lot forming unit 37 may include a lock mechanism 378 that switches between a state in which the elevating mechanism 373 and the movable hand 372 are connected and a state in which the elevating mechanism 373 and the movable hand 372 are disconnected.

When the elevating mechanism 373 raises and lowers the movable hand 372, the lock mechanism 378 connects the elevating mechanism 373 and the movable hand 372. The driving force of the elevating mechanism 373 is transmitted to the movable hand 372, and the movable hand 372 is moved up and down.

When the weight sensor 375 measures the weight of the substrate W, the lock mechanism 378 disconnects the elevating mechanism 373 and the movable hand 372. As a result, the movable hand 372 may fall along a guide 379, and a load proportional to the weight of the movable hand 372 acts on the weight sensor 375. Therefore, the weight sensor 375 may measure the weight of the substrate W.

The lot releasing unit 38 is configured in the same manner as the lot forming unit 37. Both the lot forming unit 37 and the lot releasing unit 38 are pitch conversion units that change the pitch of the substrates W while holding a plurality of substrates W.

The lot releasing unit 37 performs an operation opposite to that of the lot forming unit 37, thereby dissembling a plurality of (e.g., 50) substrates W arranged at the second pitch P2 into a plurality of (e.g., 25) substrates W arranged at the first pitch P1 and a plurality of (e.g., 25) substrates W arranged at the same first pitch P1.

The lot releasing unit 38 may have a weight measuring unit as well as the lot forming unit 37. The lot forming unit 37 measures the weight of the substrate W before being processed by the processing block 4, whereas the lot releasing unit 38 measures the weight of the substrate W after being processed by the processing block 4.

As illustrated in FIG. 1, the processing block 4 includes, for example, a processing module 41 that performs a removal process for removing a part of the substrate W. The removal process includes a process of etching the substrate W. The removal process may also include a process of peeling off the resist film formed on the substrate W or a process of polishing the substrate W. There may be a plurality of processing modules 41, and the plurality of processing modules 41 perform the same removal processing on different substrates W.

The processing block 4 includes a second transfer unit 42 that transfers the substrate W between the processing module 41 and the relay block 3. The second transfer unit 42 transfers the substrate W in lot units. The second transfer unit 42 receives the substrate W from the lot forming unit 37 and transfers the substrate W to the processing module 41, the drying module 43, and the lot releasing unit 38 in this order.

The processing block 4 may further include a second processing module that performs processing different from that of the processing module 41 on the substrate W. The second processing module is configured in the same manner as the processing module 41, but processes the substrate W using a processing liquid different from that of the processing module 41. The type of the processing liquid may be three or more.

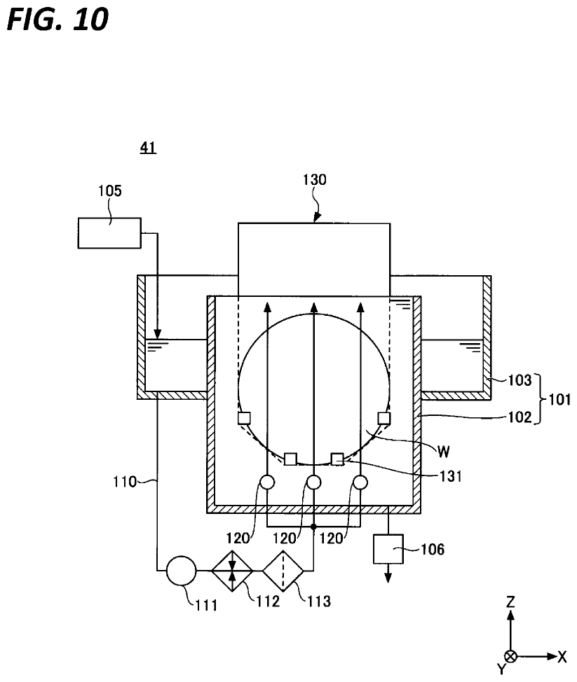

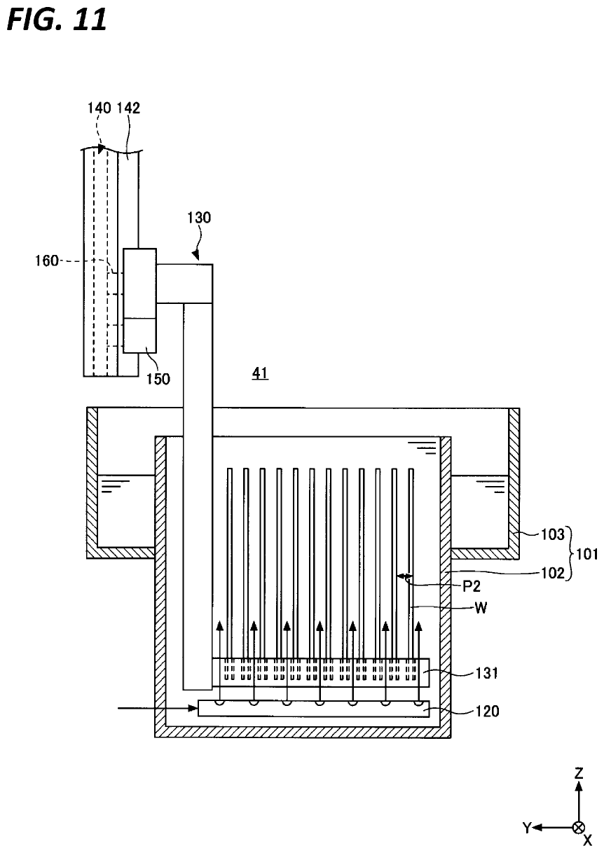

Next, the processing module 41 will be described with reference to FIGS. 10 and 11. The processing module 41 is a batch type that processes a plurality of substrates W at once. The processing module 41 includes a processing tank 101 for storing the processing liquid. The processing liquid is subjected to a removal process for removing a part of the substrate W. The processing liquid is, for example, dilute hydrofluoric acid (DHF), a mixture of hydrofluoric acid and ammonium fluoride (BHF), an aqueous phosphoric acid solution, or SC1 (mixture of ammonia, hydrogen peroxide, and water).

The processing liquid is not limited to DHF, BFH, aqueous phosphoric acid solution, and SC1, and may be, for example, dilute sulfuric acid, SPM (mixture of sulfuric acid, hydrogen peroxide, and water), SC2 (mixture of hydrochloric acid, hydrogen peroxide, and water), TMAH (mixture of tetramethylammonium hydroxide and water), or mixed acid. The mixed acid is, for example, a mixture of hydrofluoric acid (HF) and nitric acid (HNO₃), or PAN (mixture of phosphoric acid, acetic acid, and nitric acid).

As illustrated in FIG. 10, the processing tank 101 includes an inner tank 102 and an outer tank 103. The inner tank 102 is a box-shaped tank with an open upper part. The plurality of substrates W are immersed in the processing liquid stored in the inner tank 102 while being held by a holding mechanism 130 (to be described later). The outer tank 103 collects the processing liquid that overflows from the inner tank 102.

The processing module 41 includes a liquid supply 105 that supplies the processing liquid to the processing tank 101. The liquid supply 105 prepares a processing liquid by mixing a plurality of types of liquids. The liquid supply 105 includes a flow rate controller that controls the flow rate of the liquid for each liquid, and an opening/closing valve that opens and closes the flow path of the liquid for each liquid. The liquid supply 105 may change the mixing ratio of a plurality of types of liquids to change the concentration of the processing liquid.

The processing module 41 includes a liquid ejection unit 106 that ejects the processing liquid stored inside the processing tank 101 to the outside. For example, the liquid ejection unit 106 discharges the processing liquid from the bottom wall of the inner tank 102 to the outside. The liquid ejection unit 106 may eject the processing liquid to the outside from the middle of a circulation line 110 (to be described later).

The processing module 41 includes a circulation line 110 that takes out the processing liquid from the outer tank 103 and sends the processing liquid to the inner tank 102. Further, the processing module 41 includes a circulation pump 111, a temperature controller 112, and a filter 113 in the middle of the circulation line 110. The circulation pump 111 pumps the processing liquid by pressure. The temperature controller 112 is a heater, and regulates the temperature of the processing liquid. The filter 113 collects particles contained in the processing liquid.

The processing module 41 includes, for example, a horizontal pipe 120 that supplies the processing liquid to the inside of the inner tank 102. A plurality of horizontal pipes 120 extends in the Y-axis direction and is provided at intervals in the X-axis direction. The plurality of horizontal pipes 120 have a plurality of discharge ports at intervals in the longitudinal direction thereof. Each of the plurality of discharge ports discharges the processing liquid directly upward. As a result, a curtain-shaped ascending flow may be formed inside the inner tank 102. The horizontal pipes 120 may be configured so that the flow rates of the plurality of discharge ports may be controlled independently. Further, the horizontal pipe 120 may discharge a mixed fluid of a liquid and a gas. As for the gas, N₂ gas is used.

The processing module 41 includes a holding mechanism 130 that holds a plurality of substrates W. The holding mechanism 130 includes a plurality of arms 131 parallel to each other. As illustrated in FIG. 11, each arm 131 is arranged parallel to the horizontal pipe 120 (i.e., in the Y-axis direction), and vertically holds each of the plurality of substrates W arranged at the second pitch P2 in the Y-axis direction.

The processing module 41 has an elevating mechanism 140 that raises and lowers the holding mechanism 130. The elevating mechanism 140 raises and lowers the holding mechanism 130 between a position where the substrate W is immersed in the processing liquid and a position where the substrate W is loaded/unloaded.

The processing module 41 may include a weight sensor 150 on which the holding mechanism 130 is mounted. The weight sensor 150 measures a difference between the total weight of the holding mechanism 130 and the substrate W held by the holding mechanism 130, and the weight of the holding mechanism 130 to measure the weight of the substrate W. The weight sensor 150 transmits the measured data to the control device 9.

The processing module 41 may include a lock mechanism 160 that switches between a state in which the elevating mechanism 140 and the holding mechanism 130 are connected and a state in which the elevating mechanism 140 and the holding mechanism 130 are disconnected. When the elevating mechanism 140 raises and lowers the holding mechanism 130, the lock mechanism 160 connects the elevating mechanism 140 and the holding mechanism 130. The driving force of the elevating mechanism 140 is transmitted to the movable hand 130, and the holding mechanism 130 is moved up and down.

Meanwhile, when the weight sensor 150 measures the weight of the substrate W, the lock mechanism 160 disconnects the elevating mechanism 140 and the holding mechanism 130. As a result, the holding mechanism 130 may fall along a guide 142, and a load proportional to the weight of the holding mechanism 130 acts on the weight sensor 150. Therefore, the weight sensor 150 may measure the weight of the substrate W.

As illustrated in FIG. 1, the processing module 41 may further include a rinsing tank 181, a second holding mechanism 182, and a second elevating mechanism 183. The rinsing tank 181 stores a rinsing liquid in which a plurality of substrates W is immersed. The rinsing liquid is pure water such as deionized water, and the processing liquid such as an etching liquid is removed from the substrate W. The second holding mechanism 182 holds a plurality of substrates W. The second elevating mechanism 183 raises and lowers the second holding mechanism 182 between a position where the substrate W is immersed in the rinsing liquid and a position where the substrate W is loaded/unloaded.

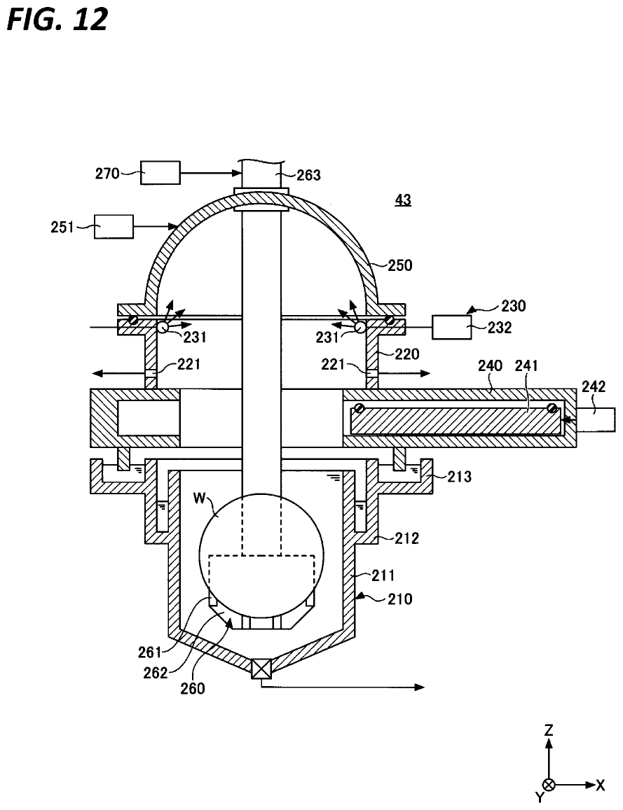

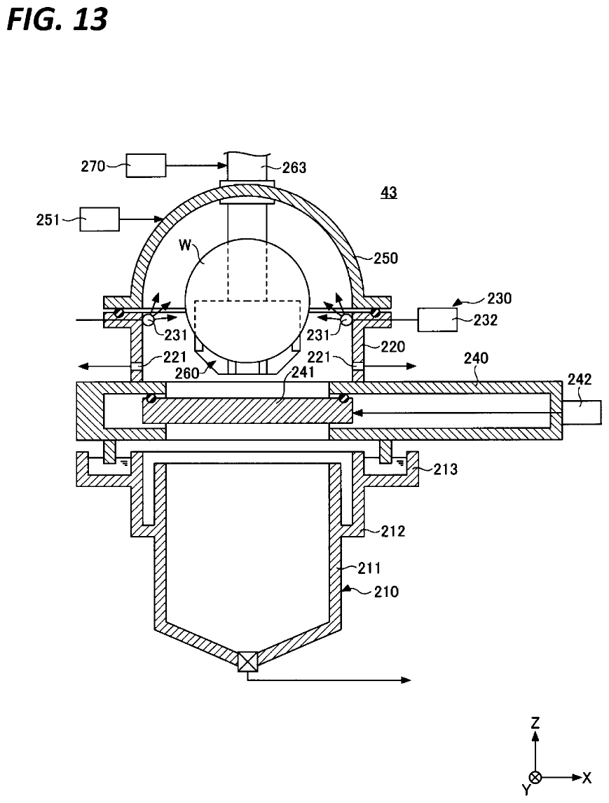

Next, the drying module 43 will be described with reference to FIGS. 12 to 14. As illustrated in FIG. 12, the drying module 43 includes a processing tank 210. The processing tank 210 stores a processing liquid in which a plurality of substrates W is immersed at once. The processing liquid is pure water such as deionized water. A layer of isopropyl alcohol (IPA) may be formed on the layer of the processing liquid. The substrate W may be pulled up from the processing tank 210 while replacing the pure water adhering to the substrate W with IPA.

The processing tank 210 includes an inner tank 211, an outer tank 212, and a seal tank 213. The inner tank 211 is a box-shaped tank with an open upper part. The plurality of substrates W are immersed in the processing liquid stored in the inner tank 211 while being held by a holding mechanism 260 (to be described later). The outer tank 212 collects the processing liquid that overflows from the inner tank 211. The seal tank 213 suppresses the intrusion of outside air with a sealing liquid contained therein.

The drying module 43 includes a cylindrical side wall 220 that surrounds the space above the processing tank 210. The side wall 220 forms a drying chamber inside where the substrate W is dried. The drying module 43 includes a gas supply 230 that supplies gas to the drying chamber. The gas supply 230 includes a nozzle 231 arranged in the drying chamber. The nozzles 231 are arranged on both sides of the substrate W. The gas supplied to the drying chamber by the nozzle 231 is ejected from an exhaust port 221 of the side wall 220.

The gas supply 230 includes a supply mechanism 232 that supplies gas to the nozzle 231. The supply mechanism 232 may supply a plurality of types of gas to the nozzle 231. The supply mechanism 232 includes a temperature controller such as a heater that regulates the temperature of gas, a flow rate controller that regulates the flow rate of gas, and an opening/closing valve that opens and closes the flow path of gas. The gas is an organic solvent gas such as IPA or N₂ gas.

The drying module 43 includes a casing 240 between the processing tank 210 and the side wall 220. A shutter 241 is movably arranged inside the casing 240. The drying module 43 includes an opening/closing mechanism 242 that moves the shutter 241. The opening/closing mechanism 242 horizontally moves the shutter 241 between a position where a lower opening of the drying chamber is opened and a position where the lower opening thereof is closed.

The drying module 43 includes a cover 250 that opens and closes the upper opening of the drying chamber, and an opening/closing mechanism 251 that moves the cover 250. The opening/closing mechanism 251 vertically moves the shutter 250 between a position where an upper opening of the drying chamber is opened and a position where the upper opening thereof is closed.

The drying module 43 includes a holding mechanism 260 that holds a plurality of substrates W. The holding mechanism 260 holds each of the plurality of substrates W arranged at the second pitch P2 in the Y-axis direction vertically upright. The holding mechanism 260 has a plurality of arms 261 parallel to each other, a bracket 262 that cantilever supports the plurality of arms 261, and an elevating rod 263 that extends directly upward from the bracket 262. The elevating rod 263 is inserted into a through hole of the cover 250, and a sealing mechanism is provided in the through hole.

The drying module 43 includes an elevating mechanism 270 that raises and lowers the holding mechanism 260. The elevating mechanism 270 raises and lowers the holding mechanism 260 between a position where the substrate W is immersed in the processing liquid (see, e.g., FIG. 12) and a position where the substrate W is loaded/unloaded. The loading and unloading of the substrate W are performed at a state where the cover 250 opens the upper opening of the drying chamber.

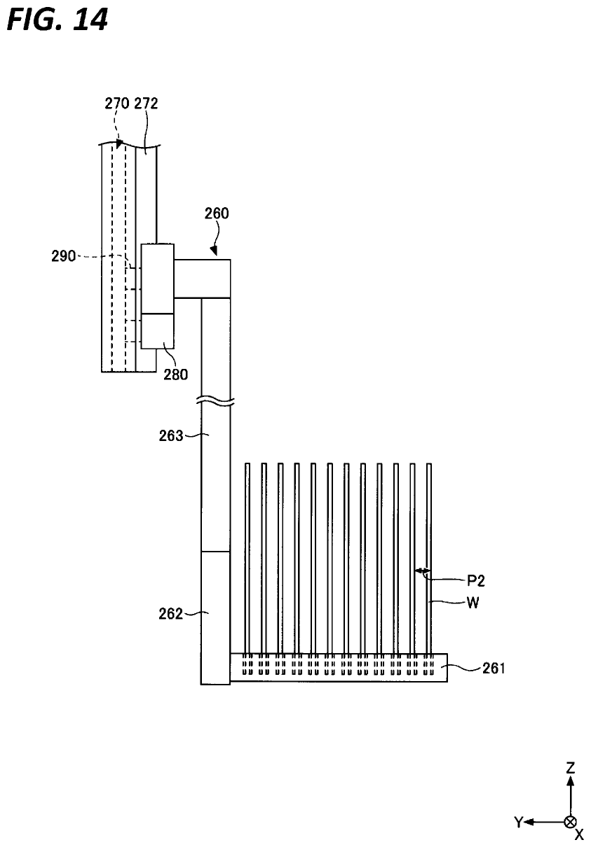

As illustrated in FIG. 14, the drying module 43 may include a weight sensor 280 on which the holding mechanism 260 is mounted. The weight sensor 280 measures a difference between the total weight of the holding mechanism 260 and the substrate W held by the holding mechanism 260, and the weight of the holding mechanism 260 to measure the weight of the substrate W. The weight sensor 280 transmits the measured data to the control device 9.

The drying module 43 may include a lock mechanism 290 that switches between a state in which the elevating mechanism 270 and the holding mechanism 260 are connected and a state in which the elevating mechanism 270 and the holding mechanism 260 are disconnected. When the elevating mechanism 270 raises and lowers the holding mechanism 260, the lock mechanism 290 connects the elevating mechanism 270 and the holding mechanism 260. The driving force of the elevating mechanism 270 is transmitted to the movable hand 260, and the holding mechanism 260 is moved up and down.

Meanwhile, when the weight sensor 280 measures the weight of the substrate W, the lock mechanism 290 disconnects the elevating mechanism 270 and the holding mechanism 260. As a result, the holding mechanism 260 may fall along a guide 272, and a load proportional to the weight of the holding mechanism 260 acts on the weight sensor 280. Therefore, the weight sensor 280 may measure the weight of the substrate W.

As illustrated in FIG. 1, the control device 9 is, for example, a computer, and includes a central processing unit (CPU) 91 and a storage medium 92 such as a memory. The storage medium 92 stores programs that control various processes executed in the substrate processing apparatus 1. The control device 9 controls the operation of the substrate processing apparatus 1 by causing the CPU 91 to execute the program stored in the storage medium 92.

Next, the operation of the substrate processing apparatus 1, that is, the substrate processing method will be described. The following operations are performed under the control of the control device 9. First, an external carrier mounts the cassette C on the mounting unit 21 of the cassette block 2. The cassette C accommodates a plurality of (e.g., 25) substrates W at the first pitch P1.

Next, the first transfer unit 23 transfers the cassette C mounted on the mounting unit 21 to the loading/unloading unit 31B in the lower stage of the relay block 3. The first transfer unit 23 may temporarily mount the cassette C on the storage unit 22 while the cassette C is being transferred from the mounting unit 21 to the loading/unloading unit 31B in the lower stage.

Next, the opening/closing mechanism 33 opens the opening of the cassette C mounted on the loading/unloading unit 31B in the lower stage. Subsequently, the single-wafer transfer unit 35 unloads the substrates W one by one from the cassette C and transfers the substrates to the alignment unit 34. The alignment unit 34 adjusts the position of the notch of the substrates W one by one and measures the weight of the substrate W. Thereafter, the substrate W is returned to the cassette C by the single-wafer transfer unit 35. When all substrates W are returned to the cassette C, the opening/closing mechanism 33 closes the opening of the cassette C. Thereafter, the first transfer unit 23 transfers the cassette C, for example, from the loading/unloading unit 31B in the lower stage to the upper loading/unloading unit 31A in the upper stage. The first transfer unit 23 may temporarily mount the cassette C on the storage unit 22 while the cassette C is being transferred from the loading/unloading unit 31B in the lower stage to the upper loading/unloading unit 31A in the upper stage.

Next, the opening/closing mechanism 33 opens the opening of the cassette C mounted on the loading/unloading unit 31B in the upper stage. Subsequently, the batch transfer unit 36 unloads a plurality of (e.g., 25) substrates W from the cassette C, and transfers the substrates W to the lot forming unit 37. The empty cassette C is transferred to the storage unit 22 by the first transfer unit 23.

Next, the lot forming unit 37 forms a lot including a plurality of (e.g., 50) substrates W. One lot includes the substrate W accommodated in two cassettes C. Further, the lot forming unit 37 may measure the weight of the substrate W before being processed by the processing block 4. Thereafter, the second transfer unit 42 receives a plurality of substrates W from the lot forming unit 37 and transfers the substrates W to the processing module 41.

Next, the processing module 41 performs a removal process for removing a part of the substrate W. The removal process is performed on a lot-by-lot basis. First, the second transfer unit 42 passes a plurality of substrates W to the holding mechanism 130. Subsequently, the elevating mechanism 140 lowers the holding mechanism 130 and immerses the plurality of substrates W in the processing liquid for a set time. The weight sensor 150 measures the weight of the substrate W after the removal process. Compared with the case where the weight of the substrate W after the removal process is measured by the relay block 3, the removal amount may be calculated at an earlier timing.

The weight sensor 150 may measure the weight of the substrate W while the elevating mechanism 140 immerses the plurality of substrates W in the processing liquid. The weight sensor 150 calculates the buoyancy acting on the substrate W from a density difference between the substrate W and the processing liquid, and corrects the measurement data. The weight sensor 150 may measure the weight of the substrate W after pulling the substrate W from the processing liquid. When the amount of droplets adhering to the substrate W is constant, the weight of the substrate W may be measured.

The timing for measuring the weight of the substrate W is not particularly limited, but when measuring the weight of the substrate W in the processing liquid, for example, immediately after immersing the substrate W in the processing liquid and immediately before pulling the substrate W out of the processing liquid. The control device 9 may stop the discharge of the processing liquid by the horizontal pipe 120 while measuring the weight of the substrate W in the processing liquid. When the flow of the processing liquid is stopped, the measurement accuracy of the weight of the substrate W may be improved.

Next, the elevating mechanism 140 raises the holding mechanism 130. Thereafter, the second transfer unit 42 receives a plurality of substrates W from the holding mechanism 130 and transfers the substrates W to the second holding mechanism 182. Subsequently, the second elevating mechanism 183 lowers the second holding mechanism 182 and immerses the plurality of substrates W in the rinsing liquid for a set time. The processing liquid remaining on the substrate W may be remounted with a rinsing liquid.

Next, the second elevating mechanism 183 raises the second holding mechanism 182. Thereafter, the second transfer unit 42 receives a plurality of substrates W from the second holding mechanism 182 and transfers the substrates W to the drying module 43. The second transfer unit 42 transmits the substrates W to the holding mechanism 260 of the drying module 43.

Next, the elevating mechanism 270 lowers the holding mechanism 260 and immerses the plurality of substrates W in the processing liquid for a set time. Subsequently, the elevating mechanism 270 raises the holding mechanism 260 and immerses the plurality of substrates W in the drying chamber. Therefore, the weight sensor 280 measures the weight of the substrate W. Thereafter, the second transfer unit 42 receives a plurality of substrates W from the holding mechanism 260 and transfers the substrates W to the lot releasing unit 38.

Next, the lot releasing unit 38 dissembles a plurality of (e.g., 50) substrates W arranged at the second pitch P2 into a plurality of (e.g., 25) substrates W arranged at the first pitch P1 and a plurality of (e.g., 25) substrates W arranged at the same first pitch P1, and releases the lot. Further, the lot releasing unit 38 may measure the weight of the substrate W after being processed by the processing block 4.

Next, the batch transfer unit 36 receives a plurality of (e.g., 25) substrates W arranged at the first pitch P1 from the lot releasing unit 38, and loads the substrates W into an empty cassette C previously mounted on the loading/unloading unit 31A in the upper stage. Subsequently, the opening/closing mechanism 33 closes the opening of the cassette C. Thereafter, the first transfer unit 23 transfers the cassette C mounted on the loading/unloading unit 31A in the upper stage to the mounting unit 21. Then, the external carrier unloads the cassette C accommodating the processed substrates W from the substrate processing apparatus 1.

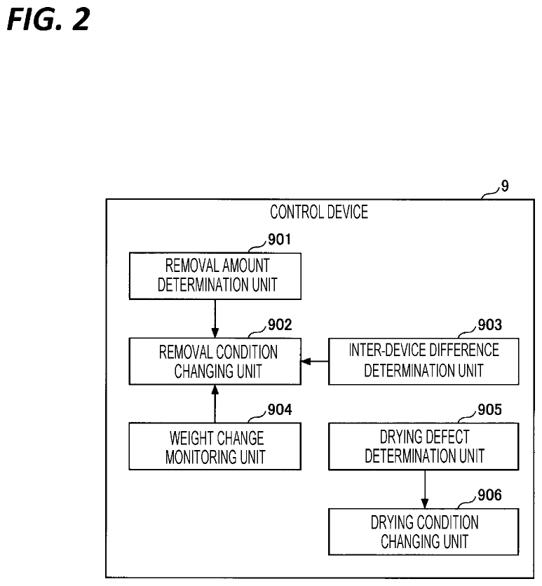

Next, the function of the control device 9 will be described with reference to FIG. 2. Each functional block illustrated in FIG. 2 is conceptual and does not necessarily have to be physically configured as illustrated. All or part of each functional block may be functionally or physically distributed/integrated in any unit. Each processing function performed in each functional block may be implemented by a program executed by a CPU in whole or in an arbitrary part, or may be implemented as hardware by wired logic.

As illustrated in FIG. 2, the control device 9 includes, for example, a removal amount determination unit 901, a removal condition changing unit 902, an inter-device difference determination unit 903, a weight change monitoring unit 904, a drying defect determination unit 905, and a drying condition changing unit 906.

The removal amount determination unit 901 calculates the weight difference of the substrate W before and after processing in the processing block 4 by using the measurement results of the weight measuring units 344 and 374 of the relay block 3, and determines whether the removal amount by the removal processing is within a permissible range. The removal amount is equal to the weight difference. The permissible range is appropriately set according to the type of removal processing and the number of substrates W. The removal amount determination unit 901 may manage the removal amount of the substrate W. Depending on the determination result of the removal amount determination unit 901, the control device 9 may change the processing conditions and notify the alarm. A permissible range may be prepared for each processing content performed according to the determination result. Therefore, a plurality of lower and upper limit values of the permissible range may be prepared. The control device 9 may notify the alarm without changing the processing conditions. The user who receives the alarm notification may consider whether to change the processing conditions.

The removal amount determination unit 901 may make a determination for each lot including a plurality of substrates W, or may make a determination for each substrate. In the latter case, the removal amount determination unit 901 may determine all of the plurality of substrates W constituting the lot, or may determine only a part thereof (e.g., both ends and the center in the arrangement direction). The position of the substrate W in the lot and the determination result of the removal amount determination unit 901 may be stored in association with each other.

The relay block 3 may separately include weight measuring units 344 and 374 that measure the weight of the substrate W before being processed by the processing block 4, and a weight measuring unit (e.g., a weight measuring unit of the lot releasing unit 38) that measures the weight of the substrate W after being processed by the processing block 4. Foreign matter adhering to the substrate W before the processing may be prevented from being transferred to the substrate W after the processing, and the substrate W after the processing may be kept clean.

The relay block 3 may include only the weight measuring units 344 and 374 that measure the weight of the substrate W before being processed by the processing block 4. The removal amount determination unit 901 may measure the weight of the substrate W after the removal process using the weight sensor 150 of the processing module 41, and determine whether the removal amount is within the permissible range. Compared with the case where the weight of the substrate W after the removal process is measured by the relay block 3, the removal amount may be calculated at an earlier timing.

The removal amount determination unit 901 may measure the weight of the substrate W before or after the removal processing by using a weight sensor other than the weight sensor of the processing module 41.

For example, the first transfer unit 23 or the second transfer unit 42 may include a weight sensor that measures the weight of the substrate W. The weight sensor is provided on a transfer arm that holds the substrate W, and receives a load corresponding to the weight of the substrate W. Therefore, the weight of the substrate W may be measured.

Further, the mounting unit 21 of the cassette block 2 may include a weight sensor for measuring the weight of the substrate W. The weight sensor measures a difference between the total weight of the cassette C and the substrate W accommodated in the cassette C, and the weight of the cassette C to measure the weight of the substrate W.

The removal condition changing unit 902 changes the processing conditions of the removal process when the removal amount determination unit 901 determines that the removal amount is outside the permissible range. The processing conditions include, for example, the processing time, the processing temperature, the concentration of the processing liquid, or the flow rate of the processing liquid. The processing time is the immersion time, and the processing temperature is the temperature of the processing liquid. When the horizontal tube 120 discharges a mixed fluid of a processing liquid and a gas, the processing condition may include the flow rate of the gas.

As described above, the position of the substrate W in the lot and the determination result of the removal amount determination unit 901 may be stored in association with each other. The removal amount may change depending on the position of the substrate W in the lot. The removal condition changing unit 902 may change the discharge flow rate of the horizontal pipe 120 for each position of the substrate W in the lot in order to reduce the variation in the removal amount in the lot.

The removal condition changing unit 902 changes the processing conditions of the removal process so that the removal amount is within the permissible range. For example, when the removal amount is too small, the removal condition changing unit 902 changes the processing time to be longer. When the removal amount is too large, the removal condition changing unit 902 changes the processing time to be shorter.

The removal condition changing unit 902 changes the processing conditions of the removal process when the removal amount determination unit 901 determines that the removal amount is outside the permissible range. That is, the removal condition changing unit 902 feedback-controls the processing conditions of the removal process.

However, the removal condition changing unit 902 may monitor the change of the removal amount with time, and may change the processing condition of the removal process when it is predicted that the next removal amount will be outside the permissible range. That is, the removal condition changing unit 902 feedback-controls the processing conditions of the removal process.

The control device 9 controls the processing module 41 according to the processing conditions changed by the removal condition changing unit 902, and performs processing on the substrate W. By changing the processing conditions by the removal condition changing unit 902, mass production of defective products may be avoided.

The inter-device difference determination unit 903 determines whether there is a difference in the removal amount among the processing modules 41 that perform the same removal process on different substrates W. The difference in the removal amount is caused by, for example, a difference in the installation location, direction, or structure of the processing module 41.

Therefore, the removal condition changing unit 902 may change the processing condition of the removal process when the inter-device difference determination unit 903 determines that there is a difference in the removal amount among the processing modules 41. The change of the processing condition may be a feedback control or feedforward control.

The removal condition changing unit 902 changes the processing conditions of the removal process so that there is no difference in the removal amount among the processing modules 41. The fact that there is no difference in the removal amount means that, for example, the difference in the average value of the removal amount is within the permissible range. The removal condition changing unit 902 may change the processing conditions of at least one processing module 41.

The control device 9 controls the processing module 41 according to the processing conditions changed by the removal condition changing unit 902, and performs processing on the substrate W. By changing the processing conditions by the removal condition changing unit 902, it is possible to reduce the difference in processing quality among the processing modules 41.

The weight change monitoring unit 904 monitors the weight change of the substrate W in the processing liquid by using the weight sensor 150 of the processing module 41. During the removal process of the substrate W, the removal condition changing unit 902 may change the processing conditions so that the removal amount of the substrate W is within the permissible range.

The drying defect determination unit 905 measures the weight of the substrate W after drying using the weight sensor 280 of the drying module 43, and determines the presence or absence of drying defects. Poor drying means, for example, that droplets are attached to the substrate W.

The drying defect determination unit 905 determines that there is a drying defect when the weight of the substrate W after drying exceeds a threshold value. Further, the drying defect determination unit 905 determines that there is a drying defect when the weight of the substrate W after drying is equal to or less than the threshold value. Depending on the determination result of the removal amount determination unit 905, the control device 9 may change the processing conditions and notify the alarm.

The drying defect determination unit 905 may make a determination for each lot including a plurality of substrates W, or may make a determination for each substrate. In the latter case, the removal amount determination unit 905 may determine all of the plurality of substrates W constituting the lot, or may determine only a part thereof (e.g., both ends and the center in the arrangement direction). The position of the substrate W in the lot and the determination result of the removal amount determination unit 905 may be stored in association with each other.

The drying condition changing unit 906 changes the processing conditions of the drying module 43 when the drying defect determining unit 905 determines that there is a drying defect. The processing conditions include, for example, the processing time, the processing temperature, the concentration of the processing liquid, or the flow rate of the processing liquid. The processing temperature is the temperature of the gas.

The drying condition changing unit 906 changes the processing conditions of the drying process so that the drying defect disappears. For example, when there is a drying defect, the drying condition changing unit 906 changes the processing time to be longer or changes the processing temperature to be higher. Such a change may be a feedback control or feedforward control.

Further, as described above, the position of the substrate W in the lot and the determination result of the drying defect determination unit 905 may be stored in association with each other. The determination result may change depending on the position of the substrate W in the lot. The drying condition changing unit 906 may change the discharge flow rate of gas for each position of the substrate W in the lot in order to reduce the rate of drying defects.

The control device 9 controls the drying module 43 according to the processing conditions changed by the drying condition changing unit 906, and performs processing on the substrate W. By changing the processing conditions by the drying condition changing unit 906, mass production of defective products may be avoided.

### Second Embodiment

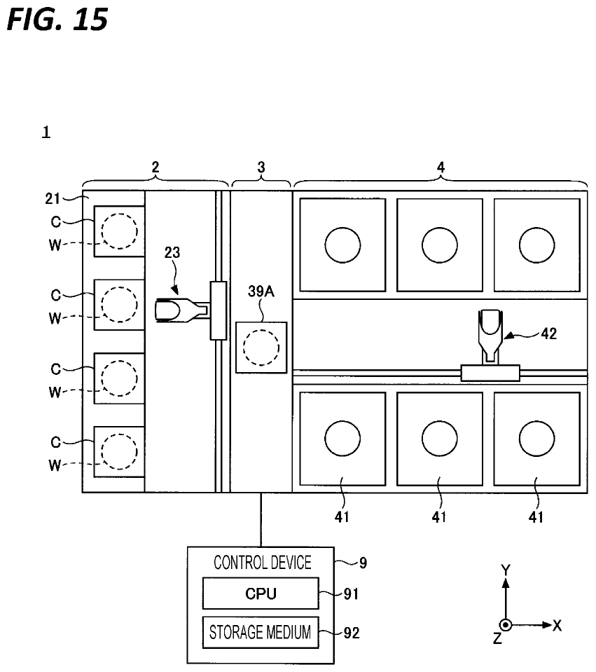

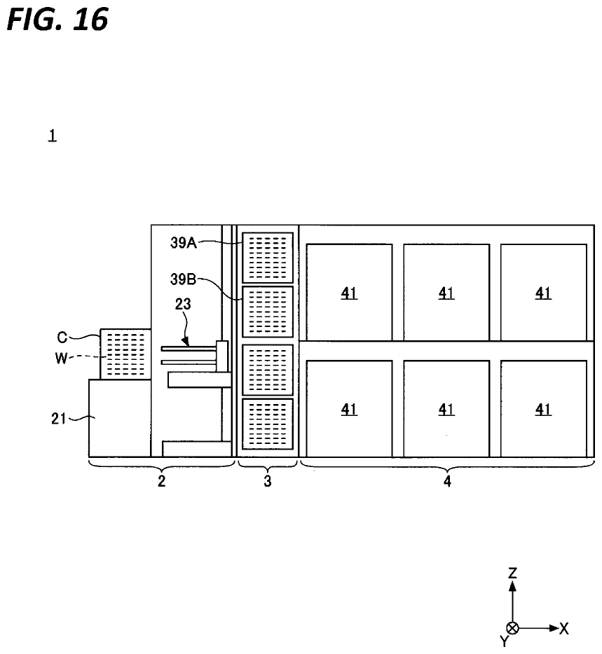

The substrate processing apparatus 1 illustrated in FIGS. 15 and 16 is a single-wafer type. Hereinafter, the differences between the present embodiment and the above-described embodiment will be mainly described. The substrate processing apparatus 1 includes a cassette block 2, a relay block 3, a processing block 4, and a control device 9. The cassette block 2 mounts a cassette C. The cassette C accommodates a substrate W. The processing block is subjected to a removal process for removing a part of the substrate W. The relay block 3 relays the substrate W between the cassette block 2 and the processing block 4. The cassette block 2, the relay block 3, and the processing block 4 are arranged in this order in the positive direction of the X-axis.

The cassette block 2 has a mounting unit 21 on which the cassette C is mounted. The cassette C accommodates a plurality of (e.g., 25) substrates W, and is loaded into and unloaded from the cassette block 2. The cassette C horizontally holds each of the plurality of substrates W arranged at intervals in the vertical direction.

The cassette block 2 has a first transfer unit 23 that transfers the substrate W between the mounting unit 21 and the transition units 39A and 39B of the relay block 3. The first transfer unit 23 includes a transfer arm that holds the substrate W. The transfer arm is movable in the horizontal direction and the vertical direction, and is rotatable about a vertical rotation axis.

The first transfer unit 23 takes out the substrate W from the cassette C mounted on the mounting unit 21 and mounts the substrate W on the transition unit 39A. Further, the first transfer unit 23 receives the substrate W from the transition unit 39B and transfers the substrate W to the cassette C mounted on the mounting unit 21.

The relay block 3 relays the substrate W between the cassette block 2 and the processing block 4. The relay block 3 has transition units 39A and 39B for temporarily storing the substrate W. The transition unit 39A temporarily stores the substrate W before being processed by the processing block 4, and the transition unit 39B temporarily stores the substrate W after being processed by the processing block 4. Both the first transfer unit 23 and the second transfer unit 42 access the transition units 39A and 39B.

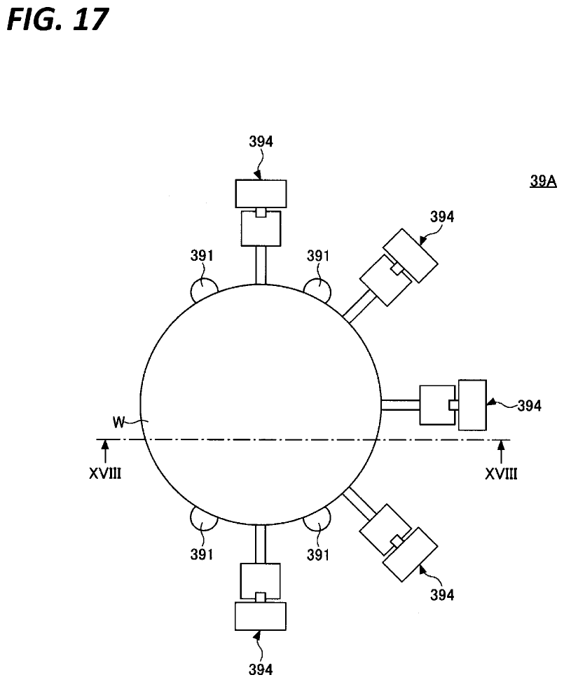

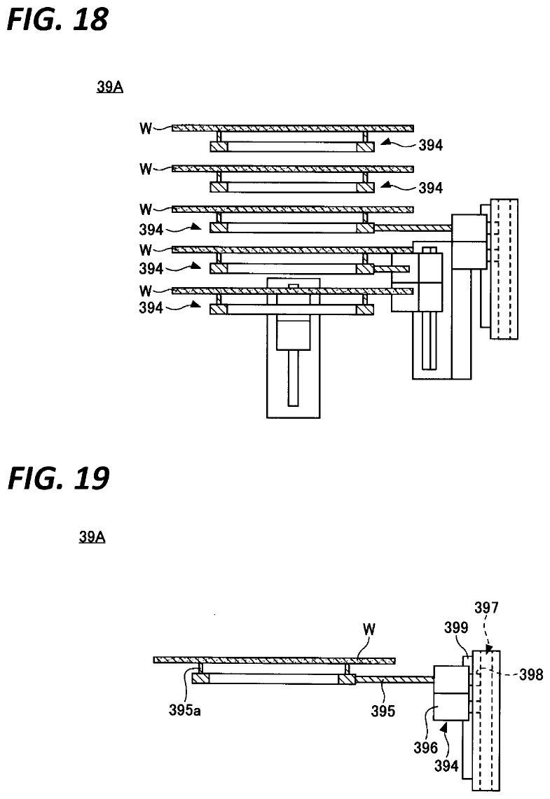

Next, the transition unit 39A will be described with reference to FIGS. 17 to 19. Since the transition unit 39B is configured in the same manner as the transition unit 39A, description and illustration thereof will be omitted.

As illustrated in FIG. 17, the transition unit 39A includes a holder 391 that holds the substrate W. The holder 391 horizontally holds each of a plurality of (e.g., 5) substrates W arranged at intervals in the vertical direction. The transition unit 37 may include a weight measuring unit 394 that measures the weight of the substrate W. A plurality of (e.g., 5) weight measuring units 394 may be provided at intervals in the circumferential direction of the substrate W.

As illustrated in FIG. 19, the weight measuring unit 394 has an arm 395 that supports the substrate W from below. The arm 395 includes, for example, a plurality of (e.g., 3) pins 395a. The plurality of pins 395a lift the substrate W from the holder 391.

Further, the weight measuring unit 394 has a weight sensor 396 on which the arm 395 is mounted. The weight sensor 396 measures a difference between the total weight of the arm 395 and the substrate W held by the arm 395, and the weight of the arm 395 to measure the weight of the substrate W. The weight sensor 396 transmits the measured data to the control device 9.

The weight measuring unit 394 has an elevating mechanism 397 that raises and lowers the arm 395 and the weight sensor 375. Further, the weight measuring unit 394 has a lock mechanism 398 that switches between a state in which the elevating mechanism 397 and the arm 395 are connected and a state in which the elevating mechanism 397 and the arm 395 are disconnected.

When the elevating mechanism 397 raises and lowers the arm 395, the lock mechanism 398 connects the elevating mechanism 397 and the arm 395. The driving force of the elevating mechanism 397 is transmitted to the arm 395, and the arm 395 is moved up and down. The weight sensor 396 measures the weight of the substrate W at a state where the arm 395 lifts the substrate W from the holder 391.

When the weight sensor 396 measures the weight of the substrate W, the lock mechanism 398 disconnects the elevating mechanism 397 and the arm 395. As a result, the arm 395 may fall along a guide 399, and a load proportional to the weight of the arm 395 acts on the weight sensor 396. Therefore, the weight sensor 396 may measure the weight of the substrate W.

The relay block 3 may separately include the transition unit 39A that measures the weight of the substrate W before being processed by the processing block 4, and the transition unit 39B that measures the weight of the substrate W after being processed by the processing block 4. Foreign matter adhering to the substrate W before the processing may be prevented from being transferred to the substrate W after the processing, and the substrate W after the processing may be kept clean.

As illustrated in FIG. 15, the processing block 4 includes, for example, a processing module 41 that performs a removal process for removing a part of the substrate W. The removal process includes etching the substrate W. The etching target is the front surface (e.g., the upper surface) of the substrate W in the present embodiment, but may be the back surface (e.g., the lower surface), both front and back surfaces, or the bevel. Further, the removal process may include peeling off the resist film formed on the substrate W or polishing the substrate W. There may be a plurality of processing modules 41, and the plurality of processing modules 41 perform the same removal processing on different substrates W.

The processing block 4 includes a second transfer unit 42 that transfers the substrate W between the processing module 41 and the relay block 3. The second transfer unit 42 includes a transfer arm that holds the substrate W. The transfer arm is movable in the horizontal direction and the vertical direction, and is rotatable about a vertical rotation axis. The second transfer unit 42 receives the substrate W from the transition unit 39A, and transfers the substrates W to the processing module 41 and the transition unit 39B in this order.

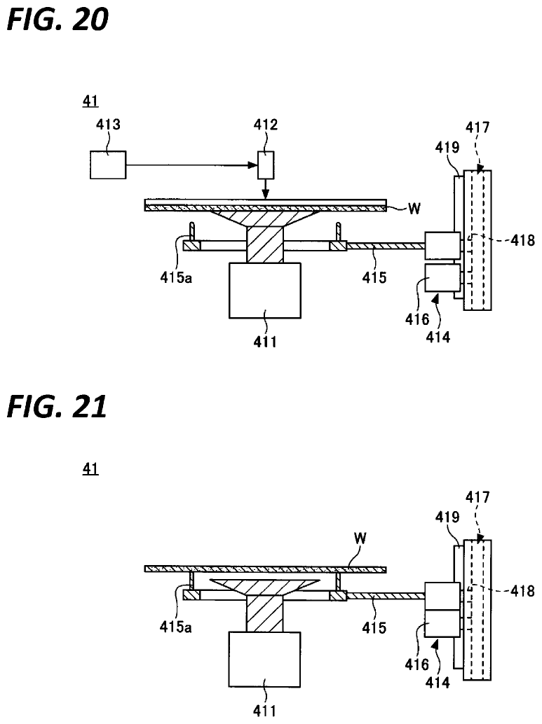

Next, the processing module 41 will be described with reference to FIGS. 20 and 21. The processing module 41 is a single-wafer type that processes the substrates W one by one. The processing module 41 includes, for example, a spin chuck 411 that sucks and rotates the substrate W, a nozzle 412 that supplies the processing liquid to the substrate W that is sucked by the spin chuck 411, and a liquid supply 413 that supplies the processing liquid to the nozzle 412.

The nozzle 412 discharges the processing liquid, for example, from above to the substrate W held horizontally by the spin chuck 411. The processing liquid is supplied to the radial center of the rotating substrate W and spreads over the entire radial direction of the substrate W by centrifugal force to process the entire upper surface of the substrate W. The number of nozzles 412 is one or more. The plurality of nozzles 412 may discharge a plurality of types of processing liquids, or one nozzle 412 may discharge a plurality of types of processing liquids.

The liquid supply 413 includes a flow rate controller that controls the flow rate of the processing liquid for each processing liquid, and an opening/closing valve that opens and closes the flow path of the processing liquid for each processing liquid. The liquid supply 413 may change the mixing ratio of a plurality of types of liquids to change the concentration of the processing liquid. Further, the liquid supply 413 may include a temperature controller such as a heater that adjusts the temperature of the processing liquid.

The processing module 41 may include a weight measuring unit 414 that measures the weight of the substrate W, as illustrated in, for example, FIG. 21. The processing module 41 measures the weight of the substrates W one by one.

The weight measuring unit 414 has an arm 415 that supports the substrate W from below. The arm 415 includes, for example, a plurality of (e.g., 3) pins 415a. The plurality of pins 415a are arranged on the outer side in the radial direction of the spin chuck 411, and lift the substrate W from the spin chuck 411.

Further, the weight measuring unit 414 has a weight sensor 416 on which the arm 415 is mounted. The weight sensor 416 measures a difference between the total weight of the arm 415 and the substrate W held by the arm 415, and the weight of the arm 415 to measure the weight of the substrate W. The weight sensor 416 transmits the measured data to the control device 9.

The weight measuring unit 414 has an elevating mechanism 417 that raises and lowers the arm 415 and the weight sensor 416. Further, the weight measuring unit 414 has a lock mechanism 418 that switches between a state in which the elevating mechanism 417 and the arm 415 are connected and a state in which the elevating mechanism 417 and the arm 415 are disconnected.

When the elevating mechanism 417 raises and lowers the arm 415, the lock mechanism 418 connects the elevating mechanism 417 and the arm 415. The driving force of the elevating mechanism 417 is transmitted to the arm 415, and the arm 415 is moved up and down. The weight sensor 416 measures the weight of the substrate W at a state where the arm 415 lifts the substrate W from the spin chuck 411.

When the weight sensor 416 measures the weight of the substrate W, the lock mechanism 418 disconnects the elevating mechanism 417 and the arm 415. As a result, the arm 415 may fall along a guide 419, and a load proportional to the weight of the arm 415 acts on the weight sensor 416. Therefore, the weight sensor 416 may measure the weight of the substrate W.

Next, the operation of the substrate processing apparatus 1, that is, the substrate processing method will be described. The following operations are performed under the control of the control device 9. First, an external carrier mounts the cassette C on the mounting unit 21 of the cassette block 2. The cassette C horizontally accommodates each of a plurality of (e.g., 25) substrates W arranged at intervals in the vertical direction.

Next, the first transfer unit 23 transfers the cassette C mounted on the mounting unit 21 to the transition unit 39A of the relay block 3. The transition unit 39A measures the weight of the substrates W one by one. Thereafter, the second transfer unit 42 receives the substrates W from the transition unit 39A and transfers the substrates W to the processing module 41.

Next, the processing module 41 performs a removal process for removing a part of the substrate W. The removal process is performed one by one. The processing module 41 may measure the weight of the substrate W after the removal process. Compared with the case where the weight of the substrate W after the removal process is measured by the relay block 3, the removal amount may be calculated at an earlier timing.

Next, the second transfer unit 42 receives the substrates W from the processing module 41 and transfers the substrates W to the transition unit 39B. The transition unit 39B measures the weight of the substrates W one by one. Thereafter, the first transfer unit 23 receives the substrates W from the transition unit 39B and transfers the substrates W to the cassette C previously mounted on the mounting unit 21.

In the present embodiment as well, as in the first embodiment, the control device 9 includes, for example, a removal amount determination unit 901, a removal condition changing unit 902, an inter-device difference determination unit 903, a weight change monitoring unit 904, a drying defect determination unit 905, and a drying condition changing unit 906. Therefore, the same effect as that of the first embodiment may be obtained.

The control device 9 transmits the weight data of the substrate W measured after being processed by the processing block 4 to a host computer in units of one substrate or lot. The host computer manages weight data transmitted from the control device 9 or state data estimated from the weight data (e.g., etching amount data). The host computer may transfer the managed data to the substrate processing apparatus of the next process and reflect the data in the substrate processing conditions of the next process.

According to an aspect of the present disclosure, a removal amount determination unit may control a removal amount for removing a part of a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a cassette block configured to mount a cassette that accommodates a substrate;
a processing block configured to process the substrate;
a relay block configured to relay the substrate between the cassette block and the processing block; and
a controller,
wherein the cassette block includes a mounting stage on which the cassette is mounted, and a first transfer unit including a first arm that transfers the substrate between the mounting stage and the relay block,
the processing block includes a processing module including a rinsing tank that performs a removal process of removing a part of the substrate, and a second transfer unit including a second arm that transfers the substrate between the processing module and the relay block,
the relay block includes a weight measuring unit including a support arm that measures a weight of the substrate before or after being processed by the processing block, and
the controller includes a removal amount determination circuit that calculates a weight difference of the substrate before and after being processed by the processing block using a measurement result of the weight measuring unit and determines whether a removal amount by the removal process is within a permissible range.

2. The substrate processing apparatus according to claim 1, wherein the controller includes a removal condition changing circuit that changes a processing condition of the removal process when the removal amount determination unit determines that the removal amount is outside the permissible range.

3. The substrate processing apparatus according to claim 1, wherein the processing block includes a plurality of processing modules each including the rinsing tank that performs the same removal process on different substrates, and
the controller includes an inter-module difference determination circuit that determines whether there is a difference in the removal amount among the plurality of processing modules that perform the same removal process on the different substrates.

4. The substrate processing apparatus according to claim 1, wherein the removal process includes etching the substrate, peeling a resist film formed on the substrate, and polishing the substrate.

5. The substrate processing apparatus according to claim 1, wherein the relay block separately includes a weight measuring unit including a support arm that measures the weight of the substrate before being processed by the processing block, and a weight measuring unit including a support arm that measures the weight of the substrate after being processed by the processing block.

6. The substrate processing apparatus according to claim 1, wherein the mounting stage, the first transfer unit or the second transfer unit include a weight sensor that measures the weight of the substrate.

7. The substrate processing apparatus according to claim 1, wherein the processing module is a batch type that processes a plurality of substrates in a batch.

8. The substrate processing apparatus according to claim 7, wherein the relay block includes a pitch converter that changes a pitch of the substrate while holding the plurality of substrates, and
the pitch converter includes the weight measuring unit.

9. The substrate processing apparatus according to claim 7, wherein the relay block includes an aligner that adjusts a position of a notch or an orientation flat of the substrate, and
the aligner includes the weight measuring unit.

10. The substrate processing apparatus according to claim 7, wherein the rinsing tank of the processing module stores a processing liquid in which a plurality of substrates is immersed in a batch, a holder that holds the plurality of substrates, and a weight sensor on which the holder is mounted.

11. The substrate processing apparatus according to claim 10, wherein the removal amount determination circuit measures the weight of the substrate after removal process using the weight sensor of the processing module and determines whether the removal amount is within a permissible range.

12. The substrate processing apparatus according to claim 10, wherein the controller includes a weight change monitoring circuit that monitors a weight change of the substrate in the processing liquid using the weight sensor of the processing module.

13. The substrate processing apparatus according to claim 7, wherein the processing module includes a drying chamber that dries the plurality of substrates in a batch, and
the drying chamber includes a processing tank that stores a processing liquid in which the plurality of substrates are immersed in a batch, a holder that holds the plurality of substrates, and a weight sensor on which the holder is mounted.

14. The substrate processing apparatus according to claim 13, wherein the controller includes a drying defect determination circuit that measures the weight of the substrate after drying using the weight sensor of the drying module and determines a presence or absence of drying defects.

15. The substrate processing apparatus according to claim 14, wherein the controller includes a drying condition changing circuit that changes a processing condition of the drying chamber when the drying defect determination circuit determines that there is a drying defect.

16. The substrate processing apparatus according to claim 1, wherein the processing module is a single-wafer type that processes the plurality of substrates one by one.

17. The substrate processing apparatus according to claim 16, wherein the relay block includes a transition chamber accessed by the first transfer unit and the second transfer unit, and
the transition chamber includes a holder that holds the substrate, and the weight measuring unit.

18. The substrate processing apparatus according to claim 17, wherein the relay block separately includes a transition chamber that measures the weight of the substrate before being processed by the processing block, and a transition chamber that measures the weight of the substrate after being processed by the processing block.

19. The substrate processing apparatus according to claim 16, wherein the processing module includes a spin chuck that holds and rotates the substrate, an arm that lifts the substrate from the spin chuck, and a weight sensor on which the arm is mounted.

20. A substrate processing method of processing a substrate using the substrate processing apparatus according to claim 1, the method comprising:
calculating the weight difference of the substrate before and after being processed by the processing block using the measurement result of the weight measuring unit; and
determining whether the removal amount by the removal process is within a permissible range.
